(19) United States
(12) Patent Application Publication
(10) Pub. No.: US 2008/0258798 A1
(43) Pub. Date: Oct. 23, 2008

(54) ANALOG LEVEL SHIFTER

(75) Inventors: Chih-Chien Huang, Miaoli Hsien (TW); Wei-Liang Lee, Yunlin Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/736,744

(22) Filed: Apr. 18, 2007

(51) Int. Cl. H03L 5/00

(52) U.S. Cl. 327/333

(57) ABSTRACT

An analog level shifter is provided, receiving an input voltage to generate an output voltage. In the analog level shifter, a NMOS transistor has a gate coupled to an input node where the input voltage is input. A resistance device comprises a first end coupled to source of the NMOS transistor, and a second end coupled to an output node where the output voltage is output. A current source is coupled to the output node, sinking a first current therefrom to ground.

### BACKGROUND OF THE INVENTION

1. Field of the Invention

The invention relates to an analog circuit, and in particular, to an analog level shifter with adjustable offset range.

2. Description of the Related Art

A source follower usually acts as a level shifter to provide a fixed value voltage offset in analog circuit implementation. FIG. 1 shows a conventional source follower. A NMOS M1 has a gate coupled to an input voltage V_{IN}, and a source coupled to an output node to provide an output voltage V_{OUT}. A current source is coupled to the output node, sinking a current I_{b} to ground. The voltage offset V_{OUT}−V_{IN} is inherently related to component properties such as threshold Vₜₕ and width/length ratio W/L of the NMOS M1, and the level of the current I_{b}. The threshold Vₜₕ, is a particularly dominant factor since if the gate-to-source voltage V_{GS} of the NMOS M1 does not exceed the threshold Vₜₕ, the NMOS M1 is not turned on.

With recent development of low voltage circuits, it becomes more desirable to convert voltages between minor levels lower than the threshold Vₜₕ. Implementation of the level shifter as shown in FIG. 1 becomes difficult if the threshold Vₜₕ is inflexible. FIG. 2 shows a transfer curve according to the conventional source follower in FIG. 1. The curve Ma denotes voltage transfer of FIG. 1 when the NMOS M1 is a normal NMOS. The offset Va cannot be lower than threshold Vₜₕ of the NMOS. If a native NMOS is used as the NMOS M1, the threshold Vₜₕ can be significantly reduced to render a transfer curve M_{c}. However, the offset V_{c} might be too small for use. The width/length ratio W/L of the NMOS M1 or the current I_{c} may be adjusted to increase the offset V_{c}, and the flexible range is very limited. A low voltage threshold (LVT) device may be used as the NMOS M1 to render a transfer curve M_{b}, having an intermediate offset V_{b} between the offsets Vₐ and V_{c}. Additional masks are required to implement LVT devices, increasing costs, while flexibility of voltage transfer range remains limited. Thus, a flexible adjustable level shifter independent of the threshold gap is desirable.

### BRIEF SUMMARY OF INVENTION

An embodiment of an analog level shifter is provided, receiving an input voltage to generate an output voltage. In the analog level shifter, a NMOS transistor has a gate coupled to an input node where the input voltage is input. A resistance device comprises a first end coupled to source of the NMOS transistor, and a second end coupled to an output node where the output voltage is output. A current source is coupled to the output node, sinking a first current therefrom to ground.

The NMOS transistor may be a native device or a low voltage threshold (LVT) device. The resistance device is a linear resistor or a variable resistor. Specifically, the resistance device is P-poly, N-poly, or diffusion type, and the generation of the current source uses the same type resistor as the resistance device. The addition of the resistance device eliminates the threshold gap, rendering flexible and adjustable voltage transition.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a conventional source follower,

FIG. 2 shows a transfer curve according to the conventional source follower in FIG. 1;

FIG. 3 shows an embodiment of a level shifter,

FIG. 4 shows a transfer curve according to the level shifter in FIG. 3;

FIG. 5 shows another embodiment of a level shifter; and

FIG. 6 shows an exemplary circuit for generating a current source.

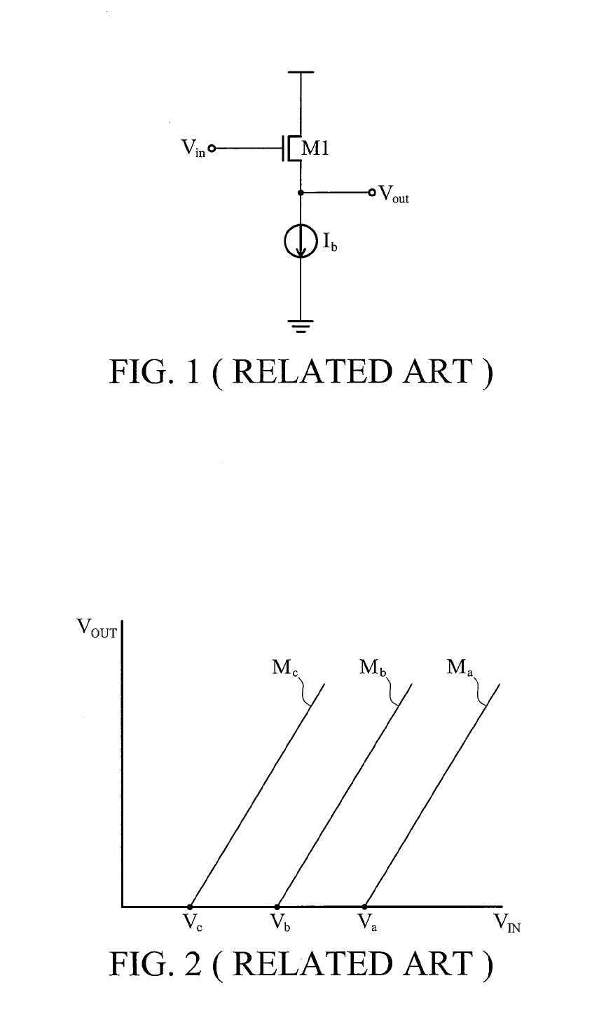

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

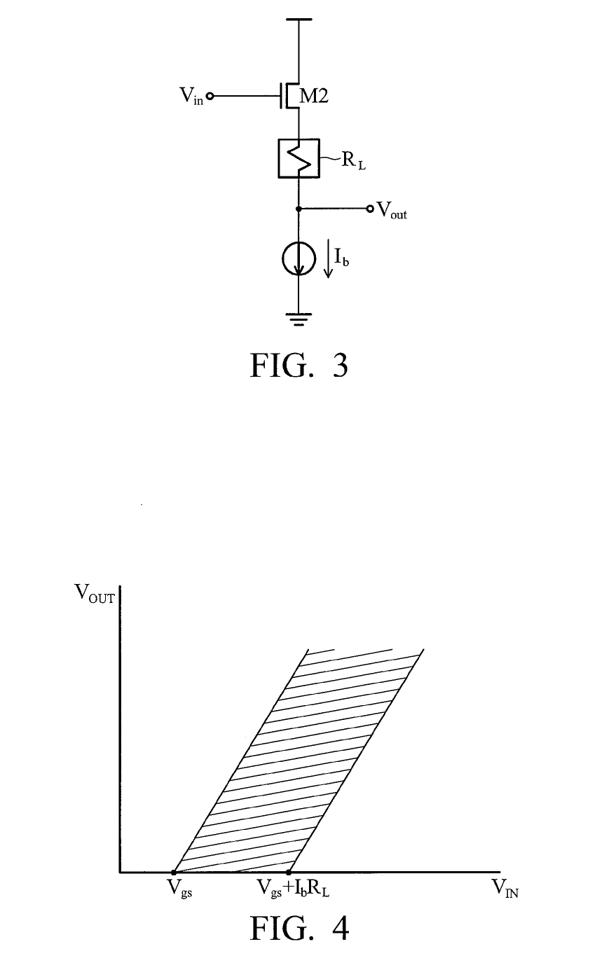

FIG. 3 shows an embodiment of a level shifter. In the analog level shifter, a NMOS M2 has a gate coupled to an input node where the input voltage V_{IN} is input. A resistance device R_{L} comprises a first end coupled to source of the NMOS M2, and a second end coupled to an output node where the output voltage V_{OUT} is output. A current source is coupled to the output node, sinking a current I_{b} therefrom to ground.

The offset between voltages V_{IN} and V_{OUT} can be expressed as:

ΔV=V_{OUT}−V_{IN}=−(V_{GS}+I_{b}R_{L}) (1)

Where V_{GS} is the gate-to-source voltage of the NMOS M2, a factor influenced by the threshold Vₜₕ. The I_{b} and R_{L} are adjustable values to compensate the influence of threshold Vₜₕ. Therefore, the voltage offset between V_{IN} and V_{OUT} can be flexibly adjusted with easy control and low cost. The NMOS transistor M2 may adopt a native device or a low voltage threshold (LVT) device.

Some fabrication processes allow fabrication of so-called “native” devices with low substrate doping concentrations. A “native” device has a deliberately different MOS channel doping to create a lower voltage threshold. Such transistors are normally unsuitable for use in digital circuits but can have great use in analog circuits. “Native” transistors can be expected to have a lower temperature coefficient of threshold voltage. This allows fabrication cost to be traded for greater analog performance. However, in general the embodiment allows good analog performance to be maintained with transistors fabricated as NMOS transistors using a fabrication process which is good for the formation of digital circuits, and hence widely available and relatively inexpensive.

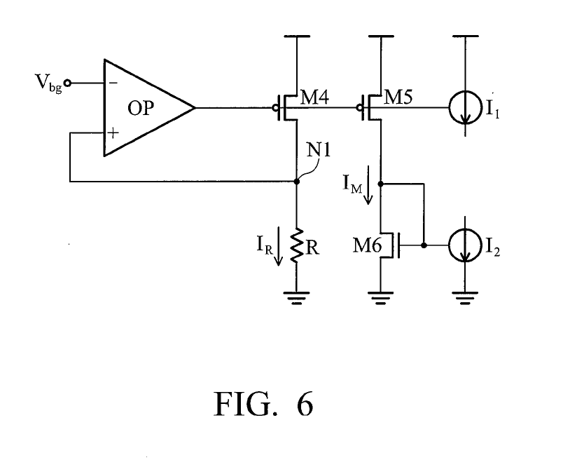

The resistance device is a linear resistor or a variable resistor. Specifically, the resistance device R_{L} is P-poly, N-poly, or diffusion type, and the generation of the current source uses the same type resistor as the resistance device. For example, as shown in FIG. 6, the current source may be generated using the formula V=IR, with the resistor used therein the same type as the resistance device R_{L}. In this way, non-linearity caused by temperature or component variations can be reduced.

FIG. 4 shows a transfer curve according to the level shifter in FIG. 3. It is shown that the combination of the resistance device eliminates the threshold gap, rendering a flexible and adjustable voltage transfer feature. The shadowed region denotes an acceptable transition range based on adjustment of the current I_{b} and resistance R_{L}. The lower bound of input voltage V_{IN} is the threshold Vₜₕ depending on the material of the NMOS M2, and the upper bound of input voltage V_{IN} depends on the multiplication of I_{b} and R_{L}. In one embodiment, adjustment of the resistance device R_{L} might be more preferable than adjustment of the current source I_{b}, because there is still minor non-linearity effect in the NMOS M2 dependent on the current I_{b}.

While the embodiment uses a NMOS to “level down” the input voltage V_{IN} to the output voltage V_{OUT}, the disclosure is not limited thereto. If a PMOS is used to implement a level shifter, the circuitry may be intuitively reversed to render a “level up” transition diagram.

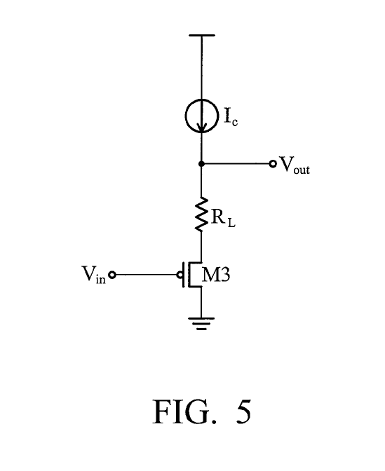

FIG. 5 shows another embodiment of a level shifter. With reference to FIG. 5, a gate of PMOS M3 is coupled to an input V_{IN}. A resistance R_{L} is coupled to a source of the PMOS M3 and V_{OUT}. A current mirror is coupled to the output node (V_{OUT}). Similar to the embodiment shown in FIG. 3, the offset between voltages V_{IN} and V_{OUT} can be expressed as:

ΔV=V_{OUT}−V_{IN}=(V_{SG}+I_{c}R_{L}) (2)

Where V_{SG} is the source-to-gate voltage of the PMOS M3, a factor influenced by the threshold V_{TH}. The I_{c} and R_{L} are adjustable values to compensate the influence of threshold Vₜₕ. Therefore, the voltage offset between V_{IN} and V_{OUT} can be flexibly adjusted with easy control and low cost. The PMOS transistor M3 may adopt a low voltage threshold (LVT) device.

FIG. 6 shows an exemplary circuit for generating a current source. With reference to FIG. 6, a voltage Vbg is input to an inverting input of an OP (operational amplifier). The voltage V_{bg} could be generated by a bandgap circuit. With a close loop configuration like FIG. 6, the voltage on the node N1 is virtually the same as that on the inverting input. That is, the voltage on the node N1 is also V_{bg}. The current flowing through R would be I_{R}=V_{bg}/R. The transistors M4, M5, and M6 constitute a current mirror, mirroring I_{R} into I_{M} with a ratio. By the same mirroring technique, current sources I₁ and I₂ can be implemented. The current source I₁ is proportional to I_{R}. The current source I₂ is also proportional to I_{R}.

Referring to FIG. 3, FIG. 5 and FIG. 6, the current source I₁ (shown in FIG. 6) could be used as the current source I_{b} (shown in FIG. 3) and the current source I₂ (shown in FIG. 6) could be used as the current source I_{c} (shown in FIG. 5). In one embodiment, the resistor R (shown in FIG. 6) can use the same type (P-poly, N-poly, or diffusion type) of resistor as that used in FIG. 3 or FIG. 5.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An analog level shifter, receiving an input voltage to generate an output voltage, comprising:
an NMOS transistor with a gate coupled to an input node where the input voltage is input;
a resistance device comprising a first end coupled to a source of the NMOS transistor, and a second end coupled to an output node where the output voltage is output; and
a current source coupled to the output node, sinking a current therefrom; wherein the resistance device is a P-poly, N-poly, or diffusion type resistor.

2. The analog level shifter as claimed in claim 1, wherein the NMOS transistor is a native device.

3. The analog level shifter as claimed in claim 1, wherein the NMOS transistor is a low voltage threshold (LVT) device.

4. The analog level shifter as claimed in claim 1, wherein the resistance device is a linear resistor.

5. The analog level shifter as claimed in claim 1, wherein the resistance device is a variable resistor.

6. (canceled)

7. The analog level shifter as claimed in claim 1, wherein the current source is driven by a resistor of the same type as the resistance device.

8. An analog level shifter, receiving an input voltage to generate an output voltage, the analog level shifter comprising:
a PMOS transistor with a gate coupled to an input node where the input voltage is input;
a resistance device comprising a first end coupled to a source of the PMOS transistor, and a second end coupled to an output node where the output voltage is output; and
a current source coupled to the output node, the current source providing a current to the resistance device: wherein the resistance device is a P-poly, N-poly, or diffusion type resistor.

9. The analog level shifter as claimed in claim 8, wherein the PMOS transistor is a low voltage threshold (LVT) device.

10. The analog level shifter as claimed in claim 8, wherein the resistance device is a linear resistor.

11. The analog level shifter as claimed in claim 8, wherein the resistance device is a variable resistor.

12. (canceled)

13. The analog level shifter as claimed in claim 8, wherein the current source is driven by a resistor of the same type as the resistance device.
